(19) United States
(12) Patent Application Publication
(10) Pub. No.: US 2015/0345007 A1
(43) Pub. Date: Dec. 3, 2015

(54) COMBINATION VAPOR DEPOSITION CHAMBER

(71) Applicant: Apple Inc., Cupertino, CA (US)

(72) Inventors: Matthew S. ROGERS, San Jose, CA (US); Kristina A. BABIARZ, San Jose, CA (US); Rodrigo A. COFINO, Cupertino, CA (US); Won B. BANG, Gilroy, CA (US); Sunggu KANG, San Jose, CA (US); Rasmi R. DAS, Sunnyvale, CA (US); Wookyung BAE, Santa Clara, CA (US); John Z. ZHONG, Cupertino, CA (US)

(73) Assignee: Apple Inc., Cupertino, CA (US)

(21) Appl. No.: 14/289,453

(22) Filed: May 28, 2014

(51) Int. Cl. C23C 14/24; C23C 14/34; C23C 14/56

(52) U.S. Cl. CPC C23C 14/24; C23C 14/568; C23C 14/34

(57) ABSTRACT

This application relates to a combination vapor deposition process chamber. In, some embodiments, a combination vapor deposition process chamber can be used to apply an optical coating to a substrate such as glass, as well as an anti-smudge coating to the same substrate. The combination vapor deposition process chamber can include a sputter target, reactive gas and plasma source, and an anti-smudge coating source. Both sputter deposition and evaporation deposition can be performed with the combination vapor deposition process chamber without exposing the substrate to open air and contaminants between deposition processes. In some embodiments, the combination vapor deposition process chamber uses multiple sub-process chambers connected by a low pressure passageway for transferring substrates between deposition processes.

### FIELD

The described embodiments relate generally to vapor deposition processes. More particularly, the present embodiments relate to performing multiple vapor deposition processes within a combination process chamber.

### BACKGROUND

Advances in manufacturing have led to the creation of many compact computing devices. The steps in manufacturing such compact devices have required strict regulation and awareness of certain environmental conditions. For example, contamination on a substrate can be a concern during a chemical deposition process because such contamination can cause differences in uniformity to layers of the processed substrate. The contamination can form during or after the chemical deposition and remain on the substrate in subsequent steps of manufacturing. For instance, between steps of manufacturing, a substrate may be exposed to atmospheric air outside of a process chamber diminishing the quality of deposited substrate layers. Although cleaning steps can be incorporated into the manufacturing process to resolve this issue, such cleaning steps can extend the manufacturing process and create opportunities for errors to be made during manufacturing. Moreover, cleaning is merely a means for handling the contamination already applied to the substrate and does not address the source of contamination.

### SUMMARY

This paper describes various embodiments that relate to vapor deposition devices, systems, and methods. In some embodiments, a process chamber for performing multiple deposition processes within the process chamber is set forth. The process chamber can include a first deposition source configured to provide a first deposit material during a first deposition process. The process chamber can also include a second deposition source configured to provide a second deposit material during a second deposition process. Additionally, the process chamber can include a target that is exposed to the first deposit material and the second deposit material during the first deposition process and the second deposition process, respectively. The process chamber can further include a shield that prevents deposition of the first deposit material on the target during the second deposition process.

In another embodiment, a process chamber is set forth as having a drum configured to rotate during multiple deposition processes occurring within the process chamber. The process chamber can also include a plurality of fixtures attached to the drum such that the plurality of fixtures attach to or clamp onto a plurality of substrates within the process chamber. Additionally, the process chamber can include an optical coating source configured to coat the substrates with an optical coating during a sputter deposition process. The process chamber can further include an anti-smudge coating source configured to coat the substrates with an anti-smudge coating during an evaporation deposition process.

In yet another embodiment, a method for applying multiple coatings to a substrate in a process chamber is set forth. The method can include a step of evacuating the process chamber and applying optical coating to a plurality of substrates. The optical coating can be applied using a sputter deposition process within the process chamber. The method can also include a step of applying anti-smudge coating to the plurality of substrates using an evaporation deposition process within the process chamber.

Other aspects and advantages of the invention will become apparent from the following detailed description taken in conjunction with the accompanying drawings which illustrate, by way of example, the principles of the described embodiments.

### BRIEF DESCRIPTION OF THE DRAWINGS

The disclosure will be readily understood by the following detailed description in conjunction with the accompanying drawings, wherein like reference numerals designate like structural elements, and in which:

FIG. 1 illustrates a perspective view of a sputter deposition chamber;

FIG. 2 illustrates a snapshot of a sputter deposition process;

FIG. 3 illustrates a perspective view of anti-smudge coating chamber;

FIG. 4 illustrates a snapshot of an anti-smudge coating process;

FIG. 5 illustrates a combination deposition chamber;

FIG. 6A illustrates a snapshot of an evaporation deposition process occurring within the combination deposition chamber of FIG. 5;

FIG. 6B illustrates a snapshot of an evaporation deposition process occurring within the combination deposition chamber of FIG. 5 wherein the fixtures and substrates are angled;

FIG. 7A illustrates an embodiment of the combination deposition chamber connected by a low pressure passageway;

FIG. 7B illustrates a snapshot of an internal view of the combination chamber connected by the low pressure passageway of FIG. 7A;

FIG. 8 outlines a method for using evaporation deposition and sputter deposition in an embodiment of the combination deposition chamber; and

FIG. 9 outlines a method for using evaporation deposition and sputter deposition in an embodiment of the combination deposition chamber having a low pressure passageway.

### DETAILED DESCRIPTION

Representative applications of methods and apparatus according to the present application are described in this section. These examples are being provided solely to add context and aid in the understanding of the described embodiments. It will thus be apparent to one skilled in the art that the described embodiments may be practiced without some or all of these specific details. In other instances, well known process steps have not been described in detail in order to avoid unnecessarily obscuring the described embodiments. Other applications are possible, such that the following examples should not be taken as limiting.

In the following detailed description, references are made to the accompanying drawings, which form a part of the description and in which are shown, by way of illustration, specific embodiments in accordance with the described embodiments. Although these embodiments are described in sufficient detail to enable one skilled in the art to practice the described embodiments, it is understood that these examples are not limiting; such that other embodiments may be used, and changes may be made without departing from the spirit and scope of the described embodiments.

Described herein are devices and methods for incorporating multiple vapor deposition processes into a process chamber. The multiple vapor deposition processes can include sputter deposition and evaporation deposition. In this way, sputter deposition and evaporation deposition can be used to apply an optical coating (e.g., an anti-reflective coating) and anti-smudge coating to a plurality of substrates in the same process chamber. By eliminating the need to transfer substrates between process chambers after a deposition process, the substrates are not exposed to ambient air. Exposing substrates to particles in ambient air can require the substrates to undergo harsh cleaning processes (e.g., plasma treatment) which can damage previously deposited layers on the substrate. Therefore, by applying the anti-reflective coating and the anti-smudge coating to substrates in the same process chamber, or a process chamber having two connected sub-process chambers, the quality and efficiency of substrate processing can be improved.

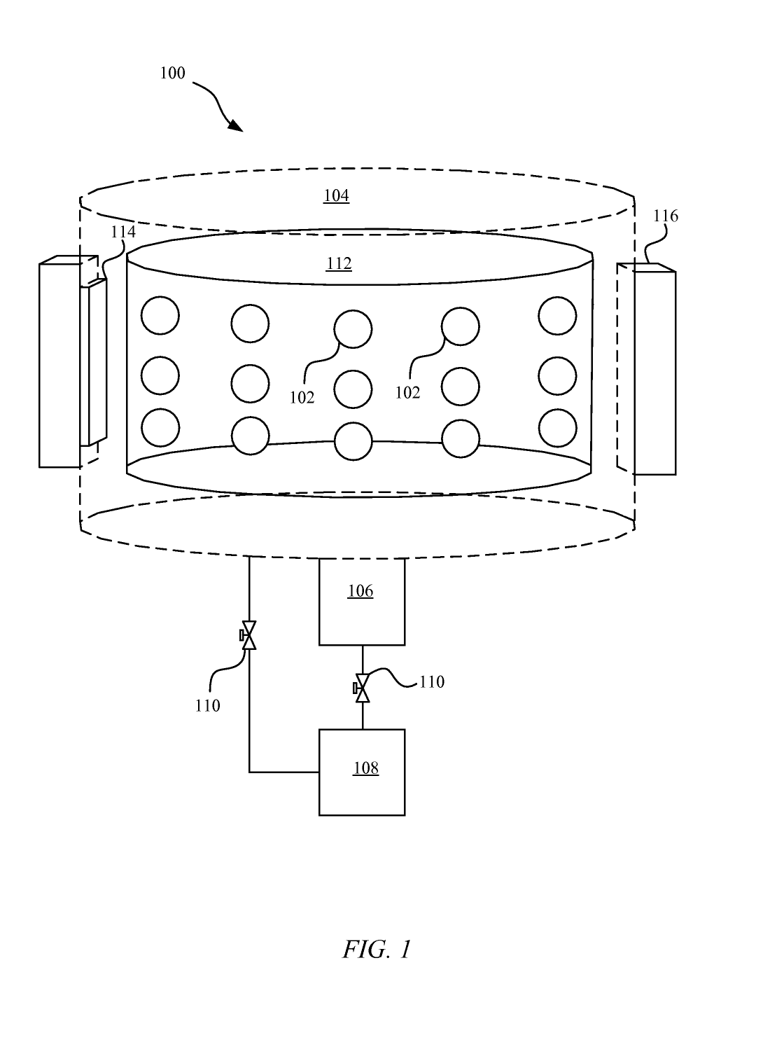

These and other embodiments are discussed below with reference to FIGS. 1-9; however, those skilled in the art will readily appreciate that the detailed description given herein with respect to these figures is for explanatory purposes only and should not be construed as limiting.

Various processes for manufacturing computing device components have led to more reliable and efficient computing devices, but also necessitated more advanced manufacturing processes. During the manufacture of certain substrates, such as glass, the substrate may encounter a variety of environments having varying pressures and temperatures. For example, various deposition processes can be iterative and sequential, requiring a substrate to go in and out of process chambers. Upon leaving a process chamber, substrates can be exposed to particles in ambient air that can stick to or react with the substrates, and possibly interfere with future deposition processes. For example, an aluminum substrate when exposed to an ambient atmosphere that includes oxygen can undergo an oxidation reaction in which a layer of aluminum oxide can form on the surface which must be removed. Additionally, a glass substrate undergoing multiple deposition processes can get ambient air particles stuck between different deposited layers, interfering with the intended properties of the deposited layers. In order to resolve these issues, certain deposition processes can be combined into a single chamber, or multiple connected chambers, as further discussed herein.

Sputter deposition and evaporation deposition are examples of deposition processes that can be combined. Sputter deposition can be used to apply an anti-reflection coating to glass, reducing the reflective qualities of the glass. During sputter deposition, substrates are attached to a rotating drum in a vacuum chamber. Once the deposition process starts, a sputter target emits coating material onto the substrate. The drum rotates during this process in order to adequately expose the surfaces of the substrates to the coating material. After the substrates are suitably coated with sputter material, the substrates can be removed from the drum and placed in another vacuum chamber for processing. However, before further processing, the substrate should be cleaned in order to remove contaminants such as hydrocarbons that can collide with the substrate outside of the vacuum chamber.

Cleaning a substrate after processing can include wet and dry methods. For example, plasma cleaning is an example of a dry method for removing contaminants from a substrate. However, plasma cleaning can damage or alter a previously applied coating. In the case of an anti-reflective coating where multiple layers are used to interfere with incidental light, a small change in a layer of anti-reflective coating can diminish the anti-reflective qualities of the anti-reflective coating and change the colors of light perceived through the substrate. Moreover, such diminishing qualities of the anti-reflective coating will be made permanent once additional coating layers are applied to the substrate. Additional coating layers can include an anti-smudge (or oleophobic) coating that enables a substrate to repel oils, fats, and similar molecules. However, if the anti-smudge coating is deposited subsequent to the substrate being exposed to contaminants the anti-smudge coating may not properly adhere to the substrate. In order to resolve the aforementioned issues, a combination deposition chamber is disclosed herein. Using a combination deposition chamber, multiple deposition processes can be incorporated into a single vacuum chamber, or multiple vacuum chambers (also referred to as sub-process chambers) connected by a sealed, low pressure, passageway so that substrates will not be exposed to contaminants between deposition processes.

The combination deposition chamber can include both an anti-smudge coating source for performing evaporation deposition of the anti-smudge coating, and an anti-reflective coating source for performing sputter deposition of the anti-reflective coating to a substrate within the combination deposition chamber. The combination deposition chamber can also include a reactive gas plasma source for injecting a reactive gas and plasma into the combination deposition chamber. As a result, the sputter target releases anti-reflective coating across the combination deposition chamber to collide with and coat the substrates, as further discussed herein. In order to protect the sputter target from receiving incident particles from other deposition processes (e.g., evaporation deposition), a shutter, or similar mechanism, can be included in the combination deposition chamber to protect the sputter target from particles moving within the combination deposition chamber.

FIG. 1 illustrates a perspective view of a sputter process chamber 100. As shown, FIG. 1 is an example of a sputter process chamber 100 that is limited to sputter processing of substrates 102. The sputter process chamber 100 operates by first applying a vacuum to the vacuum chamber 104. The vacuum chamber 104 can use a high vacuum pump 106 and a rough vacuum pump 108 in order to induce and maintain a vacuum in the vacuum chamber 104. In some embodiments, vacuum valves 110 are incorporated for sealing the vacuum chamber 104 upon the vacuum chamber 104 reaching a suitable vacuum, or venting the vacuum chamber 104 after a deposition process is complete.

Once a suitable vacuum is created within the vacuum chamber 104, the sputter process can proceed by spinning drum 112. The drum 112 can rotate at any suitable rate and in any suitable direction in order to accomplish an adequate sputtering process. The substrates 102 are attached to drum 112 such that when drum 112 rotates, the faces of the substrates 102 periodically move in front of sputter target 114. Essentially, the surfaces of the substrates 102 to be coated face outwardly from an axis of rotation of the drum 112.

The sputter target 114 is the source of anti-reflective material to be deposited onto the substrates 102. The anti-reflective material essentially “sputters” off the sputter target 114 during the sputter process, where a surface of the sputter target 114 reacts with gases inside the vacuum chamber 104 causing the sputter target 114 to release anti-reflective material from the outer surface of the sputter target 114. In order to cause the release of anti-reflective material, a reactive gas and plasma source (RGPS) 116 is incorporated into the vacuum chamber 104. The RGPS 116 introduces both a reactive gas and plasma into the vacuum chamber 104 such that the reactive gas is activated by the plasma and reacts with the surface of the sputter target 114. This reaction at the surface of the sputter target 114 causes the sputter target 114 to emit the anti-reflective material and coat the substrates 102 spinning in front of sputter target 114. The RGPS 116 can also be used to clean drum 112 after various deposition processes using a plasma cleaning process.

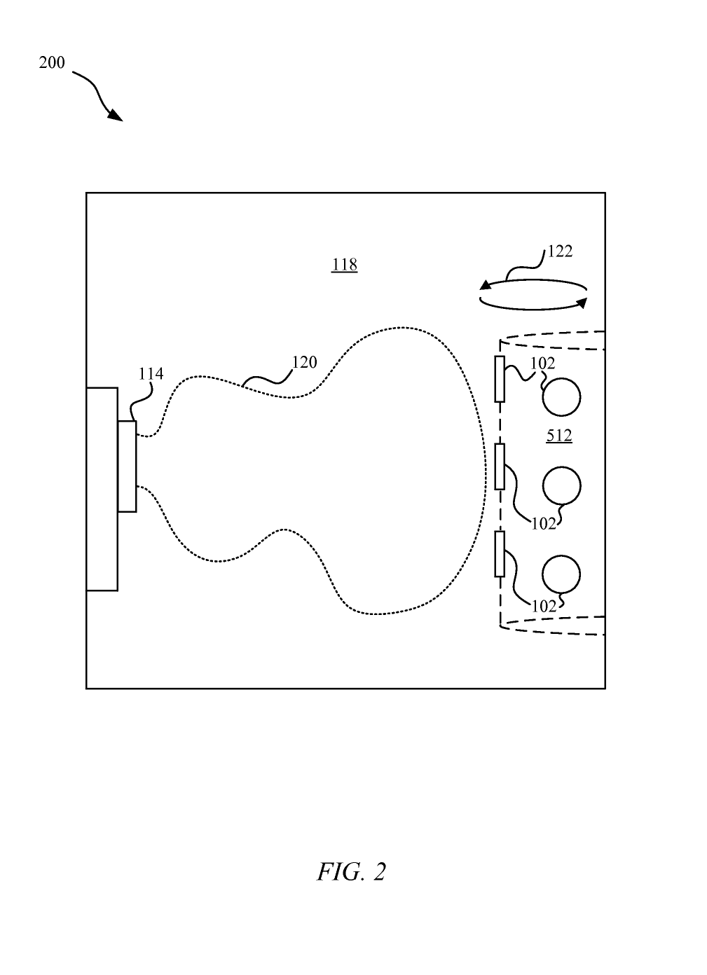

FIG. 2 illustrates a snapshot 200 of a sputter deposition process. In particular, FIG. 2 shows how anti-reflective material 120 is emitted from sputter target 114 during the sputter deposition process. Although only three substrates 102 are illustrated in FIG. 2, the sputter process can include any suitable number or arrangement of substrates 102 as further disclosed herein. The substrates 102 are processed in a low pressure environment 118 so that the anti-reflective material 120 sputters off the sputter target 114 in a substantially uninterrupted path to the spinning substrates 102. A direction of rotation 122 of drum 512 is illustrated to show how drum 112 can rotate in one embodiment in order to evenly distribute the anti-reflective material 120 among the substrates 102.

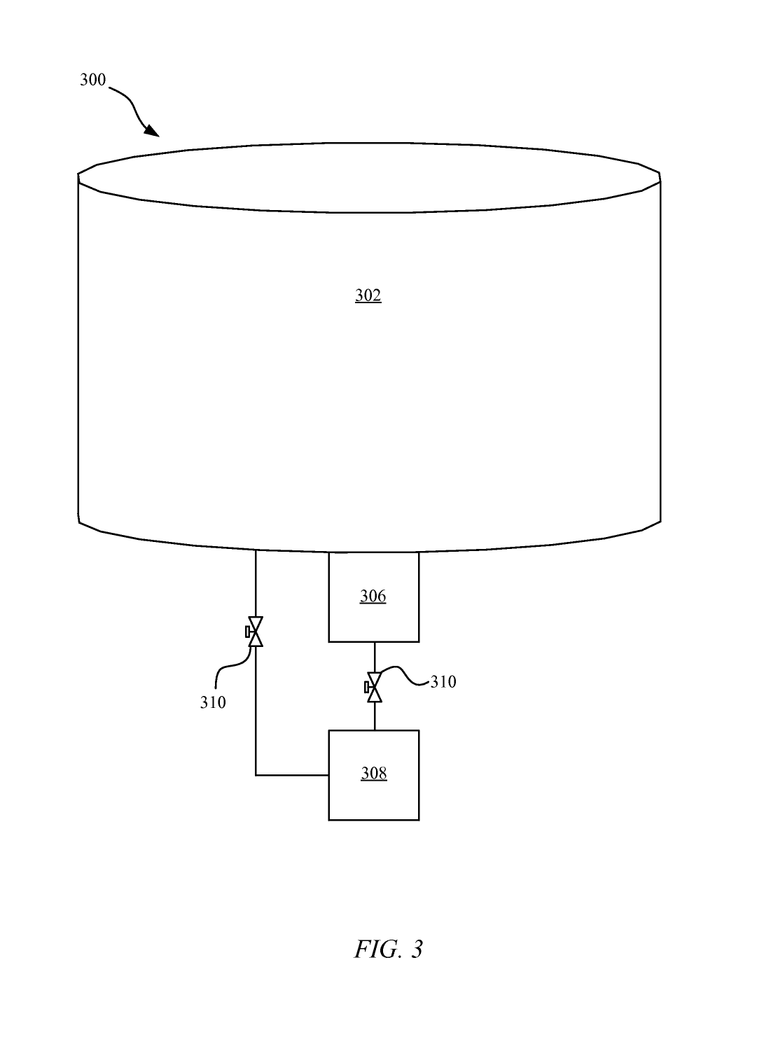

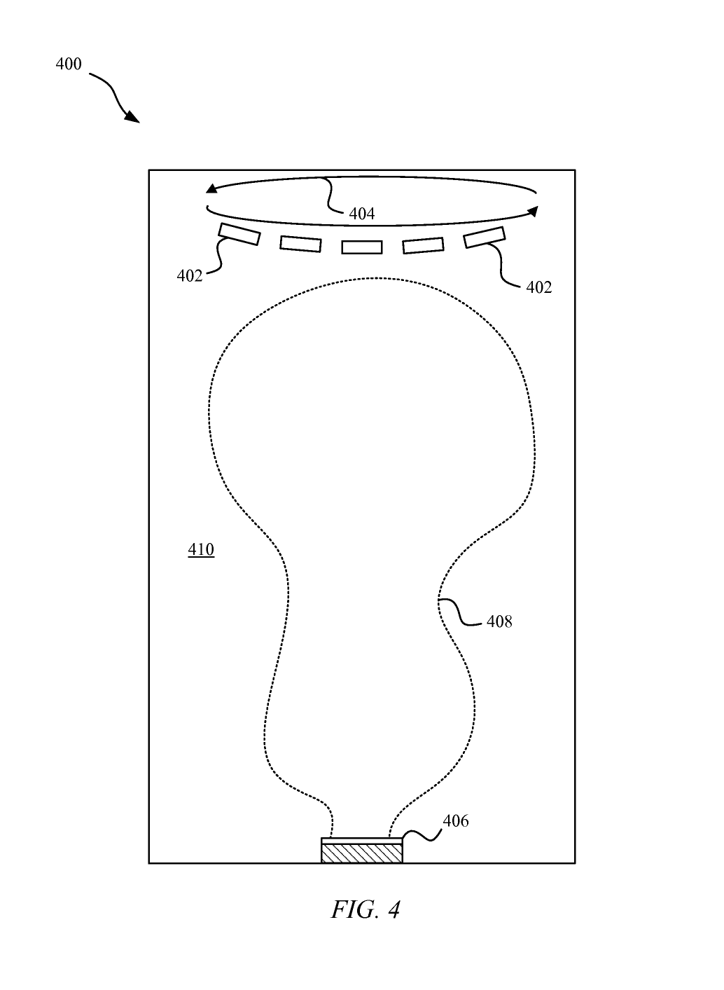

FIG. 3 illustrates a perspective view of anti-smudge coating chamber 300. Specifically, FIG. 3 shows an exterior of anti-smudge coating chamber 300 having a vacuum chamber 302 coupled to high vacuum pump 306 and rough vacuum pump 308. High vacuum pump 306 and rough vacuum pump 308 are used to induce and maintain a vacuum in the vacuum chamber 304. In some embodiments, vacuum valves 310 are incorporated for sealing the vacuum chamber 304 upon the vacuum chamber 304 reaching a suitable vacuum, or venting the vacuum chamber 304 after a deposition process is complete. Suitable vacuum can be a pressure at which the anti-smudge coating material vaporizes to accomplish an evaporation deposition process. During evaporation deposition, the anti-smudge coating material is evaporated under vacuum allowing the anti-smudge coating material to freely move from an anti-smudge coating source to one or more substrates within the vacuum chamber 304, as further illustrated in FIG. 4.

FIG. 4 illustrates a snapshot 400 of an anti-smudge coating process. Specifically, FIG. 4 illustrates how the anti-smudge coating process is accomplished using evaporation deposition. Evaporation deposition uses a low pressure environment 410 and material source 406 to coat the substrates 402 with a desired material. During an anti-smudge coating process, an anti-smudge material can be coated to the substrates 402 to give the substrates 402 an oleophobic quality. In some embodiments, the substrates 402 are spun about the vacuum chamber 304 giving the substrates 402 a rotational direction 404 in order to evenly distribute the evaporated anti-smudge material 408 among the substrates 402. The substrates 402 are fixed such that each of their surfaces to be coated face the material source 406. If the surfaces contain any contaminants or irregularities, the anti-smudge coating process may result in the anti-smudge coating being weakly adhered to the substrates 402 and potentially damage previously coated layers (e.g., a previously applied anti-reflective coating). In order to resolve these issues, the sputter process chamber 100 of FIG. 1 and anti-smudge coating chamber 300 of FIG. 3 can be combined or connected to prevent discrepancies to their respective coating processes as further discussed herein.

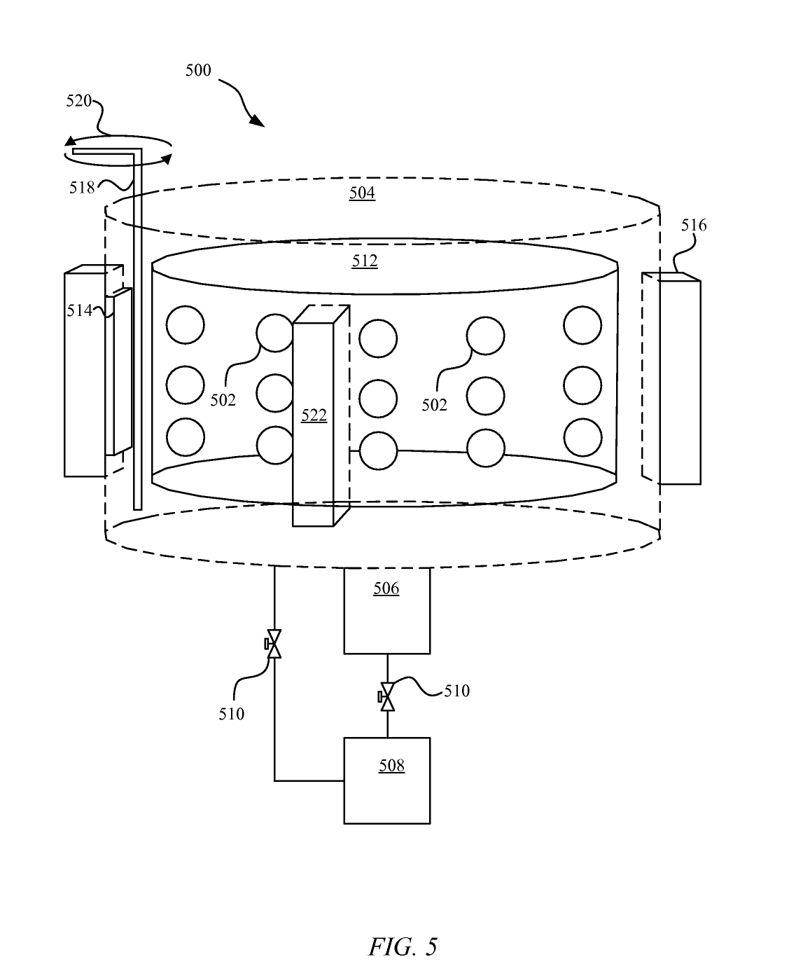

FIG. 5 shows a combination deposition chamber 500 for performing multiple deposition processes within a single vacuum chamber. Specifically, an embodiment of a configuration of the combination deposition chamber 500 is shown. The combination deposition chamber includes at least all the features and functionality of sputter process chamber 100 of FIG. 1 and anti-smudge coating chamber 300 disclosed herein. However, for purposes of further understanding the combination deposition chamber 500, embodiments of the combination deposition chamber 500 will be discussed in further detail.

The combination deposition chamber 500 can operate on a variety of substrates 502 including glass, silicon, sapphire, ceramic, polyimide, etc., alone or in combination. Combination deposition chamber 500 can include a vacuum chamber 504 coupled to a high vacuum pump 106 and a rough vacuum pump 108 in order to induce and maintain a vacuum in the vacuum chamber 504. In some embodiments, vacuum valves 510 are incorporated for sealing the vacuum chamber 504 upon the vacuum chamber 504 reaching a suitable vacuum, or venting the vacuum chamber 104 after a deposition process is complete. The number and types of vacuum pumps is not limited by FIG. 5. Accordingly, the combination deposition chamber 500 can incorporate a single vacuum pump, or any suitable number of vacuum pumps to cause the vacuum chamber 504 to reach a suitable vacuum. Moreover, the mechanism for creating a vacuum within the vacuum chamber should not be limited to pumps, but can include other means such as mechanical, electrical, thermal, etc., to induce vacuum in vacuum chamber 504.

Additionally, FIG. 5 illustrates drum 512 which can rotate during both the evaporation deposition and the sputter deposition processes inside combination deposition chamber 500. For example, during a sputter deposition process by the combination deposition chamber 500, the rotation of drum 512 allows the substrates 502 to effectively receive a desired coating layer. The drum 512 can rotate the substrates 502 at any suitable rate and in any suitable direction in order to accomplish the effective receipt of a coating layer. The substrates 502 are attached to drum 512 such that when drum 512 rotates, the faces of the substrates 502 periodically move in front of sputter target 514. The arrangement of the substrates 502 on the drum 512 is not limited to the configuration shown in FIG. 5 but can include more or less rows of substrates 502 arranged in any suitable pattern for receiving a coating layer from the sputter target 514.

In some embodiments, the sputter target 514 can be a source of anti-reflective material to be deposited onto the substrates 502. Essentially, the anti-reflective material “sputters” off the sputter target 514 during the sputter process. In order to cause the sputter target 514 to release the anti-reflective material, an RGPS 516 is incorporated into the vacuum chamber 504. The RGPS 516 introduces both a reactive gas and plasma into the vacuum chamber 504 such that the reactive gas is activated by the plasma. The reactive gas that is activated subsequently reacts with a surface of the sputter target 514. This reaction at the surface of the sputter target 514 causes the sputter target 514 to “sputter” off the anti-reflective material and is thereafter received by the substrates 502 spinning in front of sputter target 514. Gases used in the sputter deposition process can include oxygen, nitrogen, argon, or any suitable gas or combination of gases for performing sputter deposition. The sputter coating can include a variety of atoms and molecules including but not limited to titanium nitride, niobium nitride, fluorpolymers, titanium oxide, indium oxide, silicon, magnesium fluoride, zinc, tungsten, aluminum, nitrogen, or any suitable materials for providing a desirable coating. Additionally, all types of sputter deposition (e.g., direct, diode, magnetron, in-situ tilt, etc.) are considered within the scope of the disclosure, and capable of being incorporated into the various embodiments disclosed herein.

In some embodiments, drum 512 can continue spinning, or stop between a sputter deposition process and evaporation deposition process. Moreover, the substrates 502 can remain fixed between deposition processes in order to provide a more efficient substrate manufacturing process while also preventing contamination existing outside of combination deposition chamber 500 from colliding with the surfaces of the substrates 502. Additionally, because the sputter deposition process uses high vacuum, the evaporation process can follow or precede the sputter deposition process without having to substantially modify the vacuum chamber 504 environment. Moreover, the order of these processes can be modified for any suitable deposition process or manufacturing process, and can incorporate other physical and chemical deposition processes beyond sputter deposition and evaporation deposition.

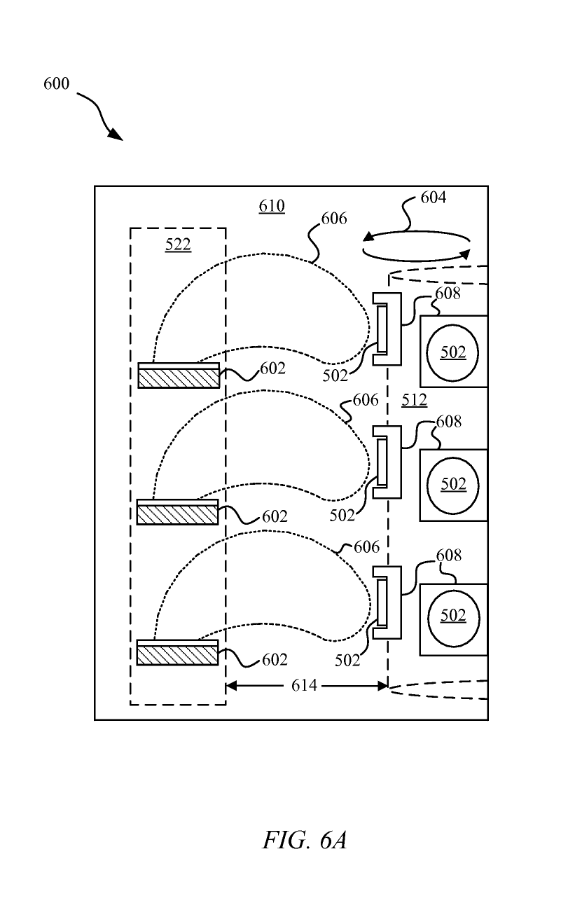

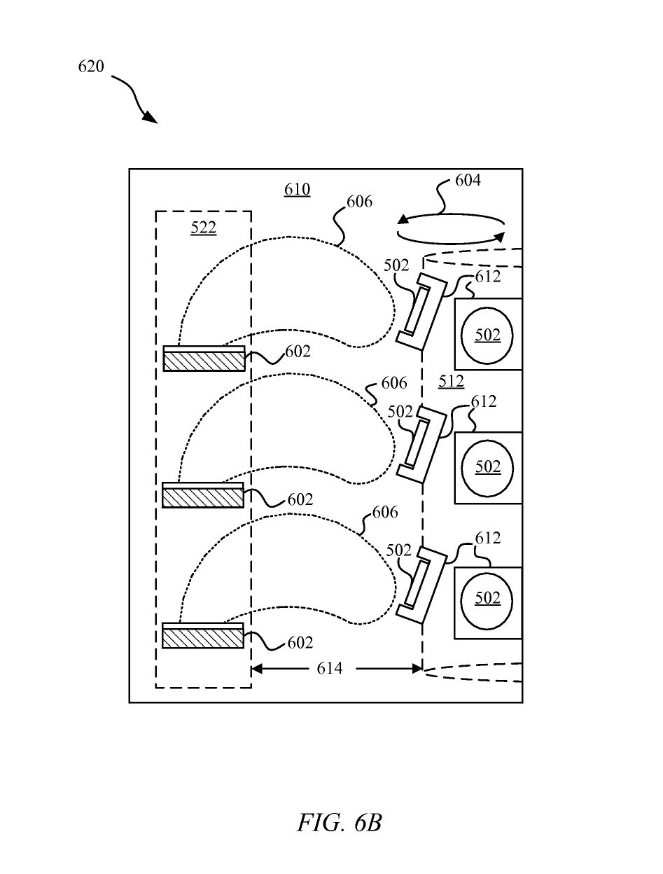

During evaporation deposition in the combination deposition chamber 500, a suitable vacuum is created, or already provided in the vacuum chamber 504 from a previous deposition process. A suitable vacuum can be a pressure at which the anti-smudge coating material vaporizes from the anti-smudge coating source 522 to accomplish an evaporation deposition process. During evaporation deposition, the anti-smudge coating material is evaporated under vacuum allowing the anti-smudge coating material to freely move from the anti-smudge coating source 522 to one or more substrates 502 within the vacuum chamber 504, as further illustrated FIGS. 6A and 6B. In some embodiments, an anti-smudge coating layer is comprised of layer of fluoropolymer, and a layer of silicon dioxide between the fluoropolymer and substrate 502. In this way, the silicon dioxide acts as an adhesive for the fluoropolymer, which provides the oleophobic properties of the anti-smudge coating. Additionally, the anti-smudge coating layer can be applied using one or more techniques of evaporation deposition (e.g., thermal, electron beam, laser, flash, resistive, etc.).

The movement of the anti-smudge coating within the vacuum chamber 504 can be problematic because of the placement of the sputter target 514 within the vacuum chamber 504. During evaporation deposition, particles of the anti-smudge coating can contaminate the sputter target 514 by colliding with the sputter target 514. In order to protect the sputter target 514 during evaporation deposition, shutter 518 (or also referred to as a shield) is configured to cover and protect the sputter target 514 by blocking particles from colliding with the sputter target 514. The shutter 518 does not interfere with the sputter deposition process because the shutter 518 can rotate (as indicated by directional arrow 520) in front of the sputter target 514 during another deposition process (i.e. evaporation deposition) and rotate away from the sputter target 514 during sputter deposition. In this way, the sputter target 514 can “sputter” particles (e.g., anti-reflective coating) without the shutter 518 interfering with the path of the particles. In some embodiments, the shutter 518 can be configured to move in a variety of ways with respect to the sputter target 514 (e.g., toward, away, up, down, etc.). Moreover, the shutter 518 can be configured to rotate on an axis of rotation that is perpendicular to the axis of rotation of the drum 512.

A pre-sputter process can be included in some embodiments of the combination deposition chamber 500. A pre-sputter process is a process to remove contamination from the sputter target 514 before performing sputter deposition on the substrates 502. During a pre-sputter process, the shutter 518 is oriented over the sputter target 514 to separate the sputter target 514 from the substrates 502 in order to prevent any coating material released during pre-sputter from ending up on the substrates 502. Subsequently, the sputter target 514 is caused to sputter a layer from the sputter target 514 so that any contaminants residing on the sputter target 514 are ejected from the sputter target 514 toward the shutter 518. The shutter 518 can then move away from the sputter target 514 in order to proceed with a sputter deposition process using a newly revealed layer of coating material on the sputter target 514. In this way, the cleaning of the sputter target 514 after the evaporation deposition, or other deposition process, conveniently occurs within the combination deposition chamber 500.

As further discussed herein, evaporation deposition in the combination deposition chamber 500 can be configured in a different manner than that of FIG. 4. In FIG. 4, material source 406 is configured below the substrates 402. A surface of each of the substrates 402 faces downward at the material source 406 in order to receive the evaporated anti-smudge material 408. Conversely, as illustrated in FIGS. 6A and 6B, multiple material sources 602 can be arranged adjacent to the substrates 502 and fixtures 608, or radially outwardly with respect to drum 512. The substrates 502 and/or the fixtures 608 can be tilted or angled, toward or away from the material sources 602, as illustrated in FIG. 6B.

FIG. 6A illustrates a snapshot 600 of an evaporation deposition process occurring within the combination deposition chamber 500. In some embodiments, the combination deposition chamber 500 can include one or more material sources 602 to emit coating material from the anti-smudge coating source 522. In this way, the low pressure environment 610 allows the material sources 602 to emit a vapor of anti-smudge coating 606 onto substrates 502. In order for the substrates 502 to adequately and evenly receive the vapor of anti-smudge coating 606, the substrates 502 can be given a rotational trajectory 604 within the vacuum chamber 504. Moreover, fixtures 608 are provided to clamp or attach onto the sides, or lateral surfaces, of the substrates 502 during rotation of the substrates 502 and drum 512 so multiple faces of each of the substrates 502 can be coated. In this way, the fixtures 608 do not overlap the surface of the substrates 502 to be coated, thereby ensuring that the each of the surfaces of the substrates 502 is fully coated. Additionally, the distance 614 between the anti-smudge coating source and the drum 512 can be modified to provide more room for the vapor of anti-smudge coating 606, or other deposited materials, to move and evenly spread out within the low pressure environment 610. Moreover, FIG. 6B illustrates an embodiment of the combination deposition chamber 620 having angled fixtures 612. The angled fixtures 612 can be oriented in any suitable manner to adequately receive a coating layer during a deposition process(es).

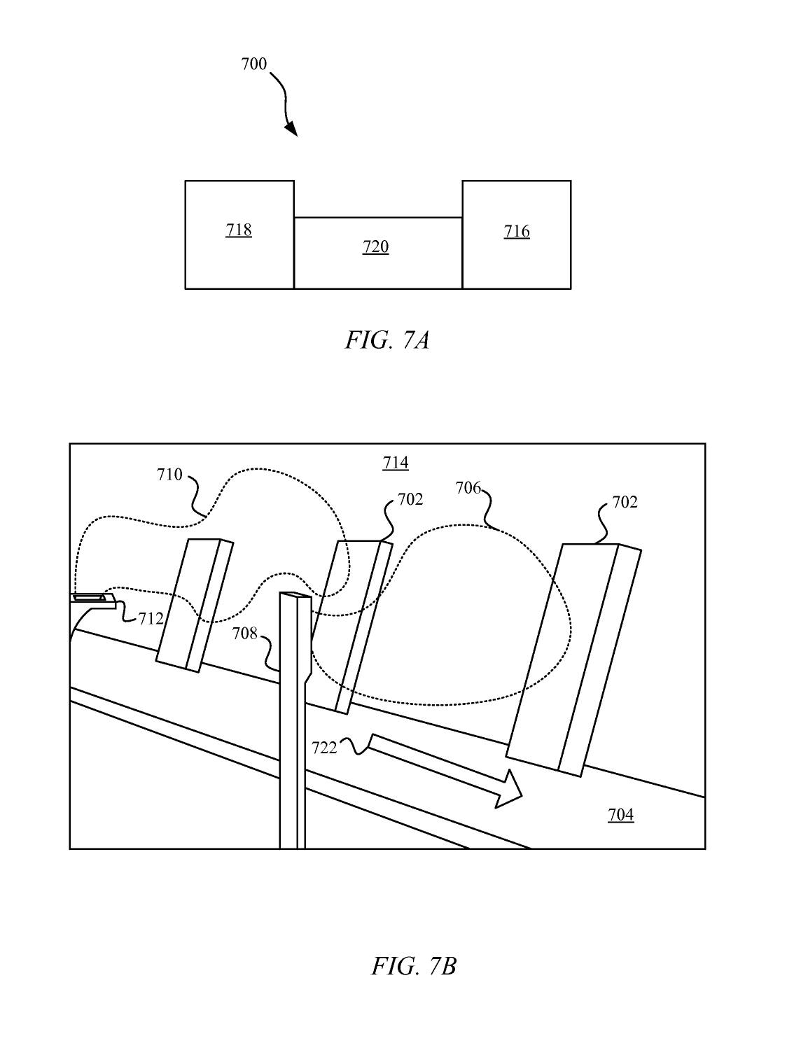

Other arrangements, modifications, and configurations for the combination deposition chamber 500 can be derived from this disclosure, and are considered to be within the scope of this disclosure. For example, the combination deposition chamber 500 can be two or more vacuum chambers (also referred to as sub-process chambers) connected by a passageway. The passageway provides a low pressure channel for the substrates 502 to pass through after or during a deposition process. In some embodiments, the sputter process chamber 100 of FIG. 1 can be connected to the anti-smudge coating chamber 300 of FIG. 3 through a passageway. In this way, the passageway provides a clean, low pressure path for the substrates 502 to pass through without being exposed to contaminants or pollutants such as hydrocarbons that can interfere with many deposition processes. Multiple passageways can be incorporated between vacuum chambers in order to provide any suitable number and arrangement of deposition processes. In some embodiments, the combination deposition chamber can be incorporated into a manufacturing process similar to a low pressure assembly line, as further illustrated in FIG. 7B.

FIG. 7A illustrates an embodiment of the combination deposition chamber 700 connected by a low pressure passageway 720. The combination deposition chamber 700 includes two sub-process chamber 718 and sub-process chamber 716. The passageway 720 is sealed, air-tight, to for maintaining a low pressure between sub-process chambers 718 and sub-process chamber 716. In some embodiments, more than two sub-process chambers are connected by one or more low pressure passageways. Additionally, the combination deposition chamber 700 can be upright, allowing a plurality of substrates within one sub-process chamber to be transferred up or down, or at an angle, to another sub-process chamber.

FIG. 7A shows a conveyor 704 carrying substrates 702 through a low pressure environment 714 within combination deposition chamber 700 of FIG. 7A. The low pressure environment 714 exists in passageway 720, which connects sub-process chamber 718 and sub-process chamber 716. A conveyor 704 is used to carry substrates 702 between sub-process chamber 716 and sub-process chamber 718 in a direction 722. A sputter target 708 in sub-process chamber 718 and material source 712 in sub-process chamber 716 are provided along a course of the conveyor 704 in order to coat the substrates 702 as the substrates 702 pass down the conveyor 704. For example, sub-process chamber 718 can be used to apply an anti-reflective coating to substrates 702 and sub-process chamber 716 can be used to apply an anti-smudge coating to substrates 702. The low pressure environment 714 and passageway 720 are configured to prevent the sputter deposition and evaporation deposition of substrates 702 from intruding upon each other. In some embodiments the conveyor 704 is replaced by an elevating mechanism in order to move the substrates 702 between various deposition processes through upward or downward movements, traversing a low pressure passageway(s) connecting the various deposition processes. The elevator mechanism can be a rising platform or fixture that carries the substrates 702 up or down through the low pressure passageway(s). Additionally, the shutter 518 of FIG. 5 can be incorporated into the combination deposition chamber for shielding the sputter target 708 in order to protect the sputter target 708 from particles emanating from other deposition processes occurring simultaneous with, or otherwise occurring around, a sputter deposition process.

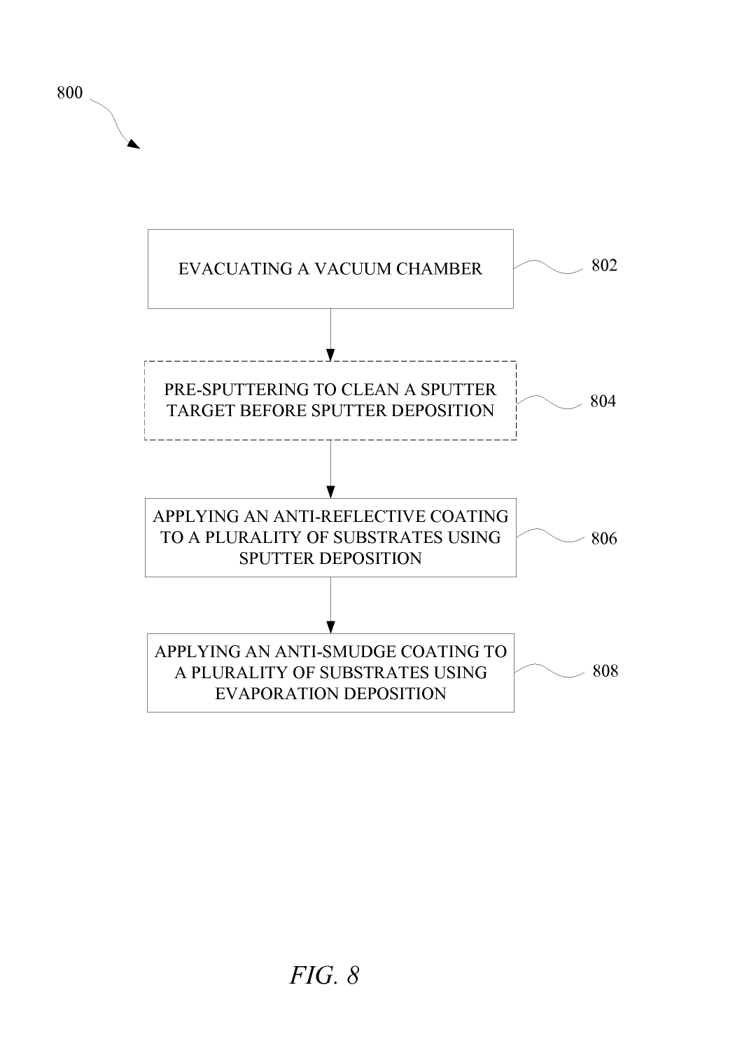

FIG. 8 outlines a method 800 for using evaporation deposition and sputter deposition in a single vacuum chamber. The method 800 includes a step 802 of evacuating a vacuum chamber, which is essential to both the evaporation deposition and sputter deposition processes because the chamber should stay in a vacuum state during both deposition processes. At step 804, which is an optional step, pre-sputtering is used to clean a sputter target before sputter deposition is commenced. Step 804 can be used to remove any materials from other deposition processes that have ended up on the sputter target, as further detailed herein. In some embodiments, a reactive gas and plasma source is used to pre-sputter an outer layer off the sputter target. At step 806, an anti-reflection coating is applied to the plurality of substrates using sputter deposition. Step 806 can be preceded by steps of fixing the substrates to a drum within the vacuum chamber, and spinning the drum, as further detailed herein. Next, at step 808, an anti-smudge coating is applied to a plurality of substrates by evaporation deposition. Method 800 can be rearranged for a variety of deposition processes and incorporate other embodiments discussed herein. For example, the method 800 can include steps of moving a shutter over and away from the sputter target for protecting the sputter target during other deposition processes such as the evaporation deposition of step 808.

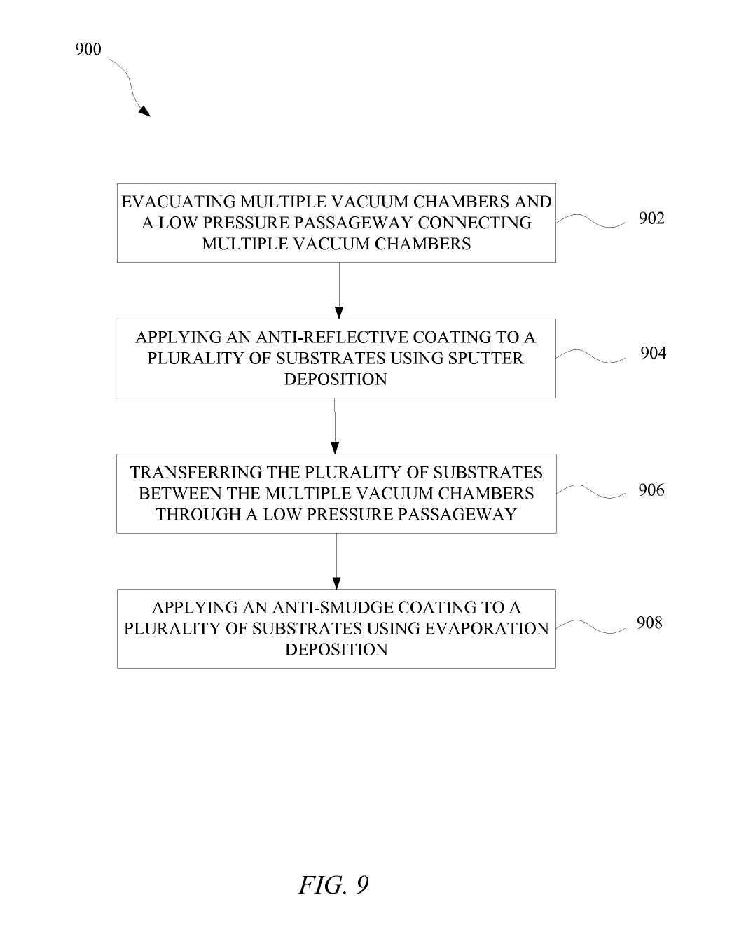

FIG. 9 outlines a method 900 for using evaporation deposition and sputter deposition in a process chamber having multiple sub-process chambers connected by a low pressure passageway coupling the multiple sub-process chambers. The method 900 includes a step 902 of evacuating the multiple sub-process chambers and the low pressure passageway connecting the multiple sub-process chambers. Next, at step 904, an anti-reflective coating is applied to a plurality of substrates using sputter deposition. Step 904 can be preceded by steps of fixing the substrates to a drum within the sub-process chamber, spinning the drum, and pre-sputtering the sputter target, as further detailed herein. At step 906, the substrates are transferred between the multiple sub-process chambers through the low pressure passageway. In this way, the low pressure passageway provides a contaminant-free path between the multiple sub-process chambers. Next, at step 908, an anti-smudge coating is applied to the plurality of substrates using evaporation deposition. Method 900 can be rearranged for a variety of deposition processes, and incorporate other embodiments discussed herein. For example, the method 900 can include steps of moving a shutter over and away from the sputter target for protecting the sputter target during other deposition processes such as the evaporation deposition of step 908. Additionally, the method 900 can include steps related to the operation of a conveyor or elevator to transfer the substrates through the low pressure passageway, as further discussed herein.

The various aspects, embodiments, implementations or features of the described embodiments can be used separately or in any combination. Various aspects of the described embodiments can be implemented by software, hardware or a combination of hardware and software. The described embodiments can also be embodied as computer readable code on a computer readable medium for controlling manufacturing operations or as computer readable code on a computer readable medium for controlling a manufacturing line. The computer readable medium is any data storage device that can store data which can thereafter be read by a computer system. Examples of the computer readable medium include read-only memory, random-access memory, CD-ROMs, HDDs, DVDs, magnetic tape, and optical data storage devices. The computer readable medium can also be distributed over network-coupled computer systems so that the computer readable code is stored and executed in a distributed fashion.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of specific embodiments are presented for purposes of illustration and description. They are not intended to be exhaustive or to limit the described embodiments to the precise forms disclosed. It will be apparent to one of ordinary skill in the art that many modifications and variations are possible in view of the above teachings.

What is claimed is:

1. A process chamber for performing multiple deposition processes within the process chamber, the process chamber comprising:
a first deposition source configured to provide a first deposit material during a first deposition process;
a second deposition source configured to provide a second deposit material onto the first deposit material during a second deposition process;
a target that is exposed to the first deposit material and the second deposit material during the first deposition process and the second deposition process, respectively; and
a shield that prevents deposition of the first deposit material on the target during the second deposition process.

2. The process chamber of claim 1, wherein a plurality of fixtures are configured to attach to a lateral portion of a substrate within the process chamber.

3. The process chamber of claim 1, wherein the shield can shift toward or away from the sputter target between the first deposition process and the second deposition process.

4. The process chamber of claim 1, wherein the target is configured to emit an anti-reflective coating into the process chamber.

5. The process chamber of claim 1, wherein the process chamber includes a reactive gas and plasma source, and the first deposition process is a sputter deposition process.

6. The process chamber of claim 1, wherein the second deposition source includes an anti-smudge coating source, and the second deposit material comprises an oleophobic material that can be applied to a plurality of substrates during the second deposition process.

7. The process chamber of claim 1, wherein the first deposition process is a sputter deposition process, the second deposition process is an evaporation deposition process, and the first deposition process and the second deposition process can be performed on a plurality of substrates within the process chamber without removing the plurality of substrates between the sputter deposition process and the evaporation deposition process.

8. The process chamber of claim 1, further comprising multiple sub-process chambers connected by a passageway configured to provide a low pressure channel for a plurality of substrates to move between before or after one of the multiple deposition processes.

9. The process chamber of claim 1, wherein the second source is configured to emit a vaporized anti-smudge coating from a plurality of sources within the process chamber.

10. The process chamber of claim 1, further comprising a plurality of fixtures configured to position a plurality of substrates such that a plurality of substrate surfaces to be coated face away from an axis of rotation of a drum within the process chamber.

11. A process chamber, comprising:
a drum configured to rotate during multiple deposition processes occurring within the process chamber;
a plurality of fixtures attached to the drum, the plurality of fixtures configured to secure a plurality of substrates within the process chamber;
an optical coating source configured to coat the substrates with an optical coating during a sputter deposition process; and
an anti-smudge coating source configured to coat the substrates with an anti-smudge coating during an evaporation deposition process, wherein the sputter deposition process and the evaporation deposition process can be performed in the process chamber without removing the substrates between the sputter deposition process and the evaporation deposition process.

12. The process chamber of claim 11, further comprising a sputter target and shutter, wherein the shutter is configured to protect the sputter target during the evaporation deposition process.

13. The process chamber of claim 11, wherein the plurality of fixtures attach to a lateral surface of the substrates, preventing the plurality of fixtures from interfering with a plurality of substrate surfaces to be coated during the multiple deposition processes.

14. The process chamber of claim 11, further comprising multiple vacuum pumps for maintaining the process chamber at a low pressure during the multiple deposition processes.

15. The process chamber of claim 11, further comprising a reactive gas and plasma source that provides oxygen or nitrogen into the process chamber during the sputter deposition process.

16. The process chamber of claim 11, further comprising multiple sub-process chambers connected by a passageway configured to provide a low pressure channel for the plurality of substrates to move between before or after one of the multiple deposition processes.

17. The process chamber of claim 11, wherein the plurality of fixtures are configured to position the plurality of substrates such that a plurality of substrate surfaces to be coated face away from an axis of rotation of the drum.

18. A method for applying multiple coatings to a plurality of substrates in a process chamber, comprising:
evacuating the process chamber;
applying a first deposit material from a first deposition source to the plurality of substrates using a first deposition process within the process chamber; and
subsequently applying a second deposit material from a second deposition source over the first deposit material on the plurality of substrates using a second deposition process within the process chamber, wherein the plurality of substrates remain in the process chamber between applying the first deposit material and applying the second deposit material.

19. The method of claim 18, further comprising covering the first deposition source with a shield to protect the first deposition source when applying the second deposit material, and pre-sputtering a layer of the first deposition source off before starting the first deposition process.

20. The method of claim 18, further comprising moving the plurality of substrates through a low pressure passageway that connects a plurality of sub-process chambers within the process chamber.
